(19) United States
(12) Patent Application Publication
(10) Pub. No.: US 2023/0243061 A1
(43) Pub. Date: Aug. 3, 2023

(54) HEAT EXCHANGE DEVICE FOR SINGLE CRYSTAL FURNACE

(71) Applicant: ZHEJIANG JINGSHENG M & E CO., LTD, Shaoxing (CN)

(72) Inventors: Jianwei CAO, Shaoxing (CN); Liang ZHU, Shaoxing (CN); Linjian FU, Shaoxing (CN); Gangfei YE, Shaoxing (CN); Junfu NI, Shaoxing (CN)

(21) Appl. No.: 17/707,957

(22) Filed: Mar. 30, 2022

Related U.S. Application Data
(63) Continuation of application No. PCT/CN2022/075165, filed on Jan. 30, 2022.

(51) Int. Cl. C30B 15/14; C30B 15/30

(52) U.S. Cl. CPC C30B 15/14; C30B 15/30

(57) ABSTRACT

A heat exchange device for a single crystal furnace is provided, including a heat exchanger on which an inner chamber for heat exchange defined in a shape of circular truncated cone is formed. A convex portion is defined by a chamber wall of the inner chamber for heat exchange partially projecting along a radial direction of the inner chamber for heat exchange, the convex portion extends along a direction of an axis of the inner chamber for heat exchange, and a minimum distance between an end away from the chamber wall of the inner chamber for heat exchange of the convex portion and the axis of the inner chamber for heat exchange is denoted as L, which is greater than or equal to a minimum radius of a cross section of the inner chamber for heat exchange.

### CROSS-REFERENCE TO RELATED APPLICATIONS

This application is a continuation of international application No. PCT/CN2022/075165, filed on Jan. 30, 2022, the content of which is hereby incorporated by reference.

### TECHNICAL FIELD

The present disclosure generally relates to a single crystal furnace, and in particular, to a heat exchange device for a single crystal furnace.

### BACKGROUND

At present, conventional heat exchange devices for single crystal furnaces usually can be divided into three kinds. The first kind is a straight-type water cooling sleeve, which is fixed in the furnace of the single crystal furnace and cannot be lifted or lowered. Since the straight-type water cooling sleeve is in a straight-shape, a visual field of the sleeve applied in the single crystal furnace is poor, resulting in the straight-type water cooling sleeve being far from a liquid level of crystallization in the furnace, and an effect of absorbing heat of crystallization is poor. The second kind is a heat exchange device by water cooling fixed at a location close to the liquid level of crystallization. A cooling effect of the heat exchange device is significant. However, the heat exchange device is too close to the liquid level of crystallization, limiting subsequent re-injection of silicon in the furnace, which greatly reduces production efficiency of the furnace. The third kind is a heat exchange device having an inverted conical shape by water cooling. Although a visual field of the heat exchange device having the inverted conical shape is good, a water cooling effect of an upper part of the heat exchange device having the inverted conical shape on a crystal rod is not as effective as a water cooling effect of a lower part of the heat exchange device having the inverted conical shape on the crystal rod, which affects uniformity and a growth rate of the crystal rod.

Therefore, it is necessary to provide a new structure of the heat exchange device for the single crystal furnace, which not only can solve a problem of the visual field of the heat exchanger device in the single crystal furnace, but can also ensure the uniformity and the growth rate of the crystal rod when the heat exchange device is in operation.

### SUMMARY

Thus, it is desired to provide a heat exchange device for a single crystal furnace to solve the above problem.

The heat exchange device for the single crystal furnace includes a lifting tube and a heat exchanger. The heat exchanger is disposed on the lifting tube and the lifting tube is capable of delivering a coolant into the heat exchanger.

The heat exchanger includes an inner chamber for heat exchange, which is in a shape of a circular truncated cone. At least one convex portion is defined by a chamber wall of the inner chamber for heat exchange partially projecting along a radial direction of the inner chamber for heat exchange, the at least one convex portion extends along a direction of an axis of the inner chamber for heat exchange, and a minimum distance between an end away from the chamber wall of the inner chamber for heat exchange of the at least one convex portion and the axis of the inner chamber for heat exchange is denoted as L, which is greater than or equal to a minimum radius of a cross section of the inner chamber for heat exchange along a direction perpendicular to the axis of the inner chamber for heat exchange.

It could be understood that the inner chamber for heat exchange of the heat exchanger is defined in the shape of the circular truncated cone, and structural characteristics of the shape of the circular truncated cone may ensure the heat exchange device has a good visual field when the heat exchange device is used in the single crystal furnace. At the same time, the convex portion can be disposed in such a way that the heat exchanger in operation may be closer to a crystal rod, thus improving a cooling effect on the crystal rod, which in turn can ensure uniformity and a growth rate of the crystal rod when the heat exchange device is used in the single crystal furnace.

In an embodiment of the present disclosure, a number of the at least one convex portion is two, and the two convex portions can be symmetrically distributed on the chamber wall of the inner chamber for heat exchange.

It could be understood that reasonable structures of the above convex portions are used to achieve the number and positions of the convex portions on the chamber wall, which can ensure uniformity of cooling for the crystal rod during operation of the heat exchanger.

In an embodiment of the present disclosure, a surface of the end away from the chamber wall of the inner chamber for heat exchange of each of the two convex portions is disposed as a cylindrical surface.

It could be understood that the surface of the end away from the chamber wall of the inner chamber for heat exchange of each of the two convex portions is disposed as a cylindrical surface to achieve a structure of a side of the two convex portions for cooling for the crystal rod, resulting in that both upper and lower portions of the two convex portions have high efficiency for heat exchange to ensure that the two convex portions can efficiently exchange heat with respect to the crystal rod in growing, thus meeting requirements of the heat exchanger when the heat exchanger is used to cool the crystal rod in the single crystal furnace.

In an embodiment of the present disclosure, a distance between the cylindrical surfaces of the two convex portions along the radial direction of the inner chamber for heat exchange is equal to a minimum diameter of the inner chamber for heat exchange.

It could be understood that the distance between the cylindrical surfaces is set to be equal to the minimum diameter of the inner chamber for heat exchange to ensure a consistent cooling effect on the crystal rod when the heat exchanger is in operation, which in turn can ensure the uniformity and the growth rate of the crystal rod when the heat exchange device is used in the single crystal furnace.

In an embodiment of the present disclosure, the heat exchange device further includes a guiding tube which is disposed on an outside of the heat exchanger. An inner wall of the guiding tube is defined as a tapered structure matching with an outer peripheral wall of the heat exchanger. A predetermined gap is formed between the tapered structure and the outer peripheral wall. An outer wall of the guiding tube is defined in a cylindrical structure.

It could be understood that the above structure of the guiding tube can divert protective gas when the heat exchange device is used in the single crystal furnace, and isolate a direct heat radiation from a heat field to the heat exchanger to avoid a reverse effect of the heat exchanger on cooling the crystal rod due to the direct heat radiation, which in turn can ensure the heat exchanger cooling for the crystal rod.

In an embodiment of the present disclosure, the guiding tube is provided with a lifting hook, and the lifting tube is provided with a connecting plate for hooks. A part away from the lifting tube of the connecting plate for hooks has at least one clamping slot, and the lifting hook can rotatably clamp into the at least one clamping slot of the connecting plate for hooks to limitedly install the guiding tube on the lifting tube.

It could be understood that a limiting installation of the guiding tube on the lifting tube is achieved by the above lifting hook and the connecting plate for hooks, resulting in that the lifting tube can drive the heat exchanger and the guiding tube to move at the same time, thus meeting requirements of lifting and lowering of the heat exchange device when the heat exchange device is used in the single crystal furnace.

In an embodiment of the present disclosure, the part away from the lifting tube of the connecting plate for hooks has a plurality of clamping slots arranged along a radial direction of the guiding tube.

It could be understood that the plurality of clamping slots can be arranged on the connecting plate for hooks, and the lifting tube can be adapted to limiting installations of guiding tubes with different sizes, which in turn allows the lifting tube to be adapted to heat exchangers with different sizes.

In an embodiment of the present disclosure, the heat exchange device can further include a lifting mechanism which can drive the heat exchanger via the lifting tube to move in a lifting and lowering motion.

It could be understood that a driving of the heat exchanger for lifting and lowering is achieved by the above lifting mechanism.

In an embodiment of the present disclosure, the heat exchange device can further include a guiding component which is penetrated by the lifting tube, and the guiding component is configured for guiding and limiting a lifting and lowering motion of the lifting tube.

It could be understood that the guide component can guide the lifting and lowering motion of the heat exchanger, ensuring stability of the heat exchanger when the heat exchanger is lifting and lowering, and avoiding interference between the heat exchanger and the crystal rod during the lifting and lowering motion.

In an embodiment of the present disclosure, the guiding component can include a first flange, a second flange, and an expansion tube for connecting the first flange and the second flange. The lifting tube is disposed on a moving portion of the lifting mechanism by the first flange, and the second flange is disposed on a fixed portion of the lifting mechanism.

It could be understood that the guiding component is achieved by the first flange, the second flange and the expansion tube, and the guiding component can stretch or compress the expansion tube in response to the lifting and lowering of the lift tube during operation.

### BRIEF DESCRIPTION OF THE DRAWINGS

FIG. 1 is a cross-sectional diagram of a heat exchange device for a single crystal furnace in an embodiment of the present disclosure.

FIG. 2 is a schematic diagram of a lifting tube and a heat exchanger assembled with each other in the present disclosure.

FIG. 3 is a schematic diagram of a lifting hook and a connecting plate for hooks assembled with each other in the present disclosure.

In the figures, 10 represents a lifting tube; 11 represents a first vertical portion; 12 represents a transverse portion; 13 represents a second vertical portion; 110 represents a connecting plate for hooks; 111 represents a clamping slot; 120 represents a flexible shaft; 20 represents a heat exchanger; 201 represents an inner chamber for heat exchange; /represents an axis of the inner chamber for heat exchange; 21 represents a chamber wall; 211 represents a convex portion; 2111 represents a cylindrical surface; 22 represents an outer peripheral wall; 30 represents a guiding tube; 31 represents an inner wall; 32 represents an outer wall; 33 represents an shrinking bottom; 310 represents a lifting hook; 311 represents a limiting end; 40 represents a lifting mechanism; 50 represents a guiding component; 51 represents a first flange; 52 represents a second flange; 53 represents an expansion tube.

### DETAILED DESCRIPTION OF THE EMBODIMENT

The technical solutions in the embodiments of the present disclosure are clearly and completely described in the following with reference to the accompanying drawings in the embodiments of the present disclosure. It is obvious that the described embodiments are only a part of the embodiments, but not all of the embodiments. All other embodiments obtained by those skilled in the art based on the embodiments of the present disclosure without making creative labor are the scope of the present disclosure.

It should be noted that when an element is considered to be “disposed on” another element, it can be directly disposed to another element, or there can be a centered element. When an element is considered to be “set on” another element, it can be directly set on another element, or there can be a centered element at the same time. When an element is considered to be “fixed to” another element, it can be directly fixed to another element, or there can be a centered element at the same time.

Unless otherwise defined, all technical and scientific terms used herein have the same meaning as a skilled person in the art would understand. The terminology used in the description of the present disclosure is for the purpose of describing particular embodiments and is not intended to limit the disclosure. The term “or/and” as used herein includes any and all combinations of one or more of the associated listed items.

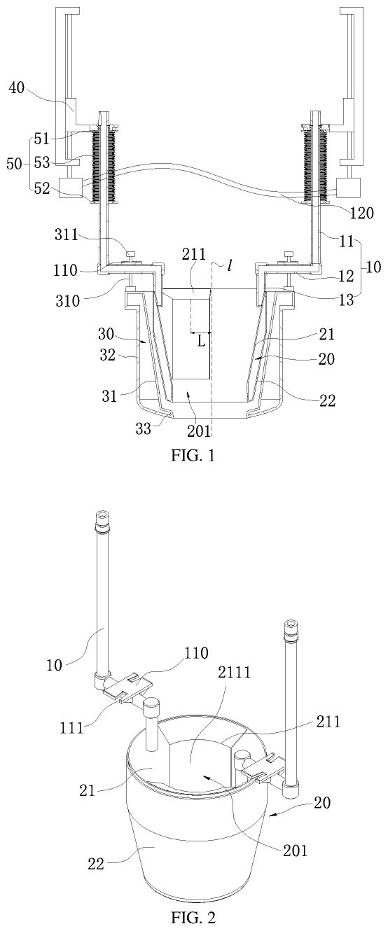

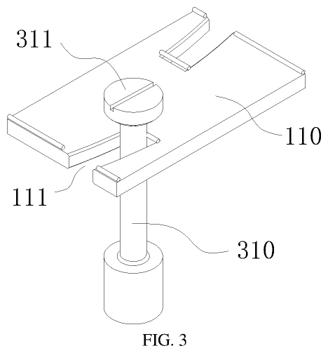

As shown in FIG. 1 to FIG. 3, a heat exchange device for a single crystal furnace provided in an embodiment of the present disclosure can include a lifting tube 10, a heat exchanger 20, a guiding tube 30, a lifting mechanism 40, and a guiding component 50.

Both the heat exchanger 20 and the guiding tube 30 can be disposed on the lifting tube 10 and the lifting mechanism 40 can drive the heat exchanger 20 and the guiding tube 30 to lift and lower through the lifting tube 10 along a growth direction of a crystal rod. In this process, a lifting and lowering motion of the lifting tube 10 can be guided and limited with the guide component 50, and the lifting tube 10 can deliver a coolant into the heat exchanger 20. It should be noted that the coolant can be cooling water.

The lifting tube 10 can include a first vertical portion 11, a transverse portion 12, and a second vertical portion 13. A moving portion (not shown) can be connected with the first vertical portion 11 of the lifting tube 10. The guiding tube 30 can be disposed on the transverse portion 12 of the lifting tube 10. The heat exchanger 20 can be disposed on the second vertical portion 13 of the lifting tube 10.

In the present disclosure, an inner chamber 201 for heat exchange can be formed on the heat exchanger 20 and defined in a shape of a circular truncated cone. At least one convex portion 211 can be defined by a chamber wall 21 of the inner chamber 201 for heat exchange partially projecting along a radial direction of the inner chamber 201 for heat exchange. The at least one convex portion 211 can extend along a direction of an axis l of the inner chamber 201 for heat exchange. A minimum distance between an end away from the chamber wall 21 of the inner chamber 201 for heat exchange of the at least one convex portion 211 and the axis l of the inner chamber 201 for heat exchange can be denoted as L, which is greater than or equal to a minimum radius of a cross section of the inner chamber 201 for heat exchange along a direction perpendicular to the axis l of the inner chamber 201 for heat exchange. In other words, when the heat exchanger 20 is in operation, the heat exchanger 20 can cool the crystal rod (not shown) via the end away from the chamber wall 21 of the inner chamber 201 for heat exchange of the at least one convex portion 211, and the at least one convex portion 211 disposed on the chamber wall 21 of the inner chamber 201 for heat exchange does not interfere with the crystal rod.

It could be understood that the inner chamber 201 for heat exchange of the heat exchanger 20 is defined in the shape of the circular truncated cone, and the chamber wall 21 of the heat exchanger 20 has a large diameter at one end and a small diameter at the other end due to structural characteristics of the shape of the circular truncated cone, ensuring that the heat exchange device has a good visual field when the heat exchange device is used in the single crystal furnace (not shown). At the same time, the convex portion 211 can be disposed in such a way that the heat exchanger in operation may be closer to the crystal rod, thus improving a cooling effect on the crystal rod, which in turn can ensure uniformity and a growth rate of the crystal rod when the heat exchange device is used in the single crystal furnace.

Specifically, a number of the at least one convex portion 211 is two, and the two convex portions 211 can be symmetrically distributed on the chamber wall 21 of the inner chamber 201 for heat exchange. The number and positions of the at least one convex portion 211 on the chamber wall 21 of the inner chamber 201 for heat exchange can ensure uniformity of cooling for the crystal rod during operation of the heat exchanger 20.

Furthermore, a length of the convex portion 211 along the direction of the axis l of the inner chamber 201 for heat exchange is equal to an axis length of the chamber wall 21.

A surface of the end away from the chamber wall 21 of the inner chamber 201 for heat exchange of the convex portion 211 is defined as a cylindrical surface 2111, thus a structure of a side of the convex portion 211 for cooling for the crystal rod can be made, resulting in that both upper and lower portions of the convex portion 211 have high efficiency for heat exchange to ensure that the convex portion 211 can efficiently exchange heat with respect to the crystal rod in growing, thus meeting requirements of the heat exchanger 20 when the heat exchanger 20 is used to cool the crystal rod in the single crystal furnace.

Secondly, a distance between two cylindrical surfaces 2111 along the radial direction of the inner chamber 201 for heat exchange is equal to a minimum diameter of the inner chamber 201 for heat exchange. The distance between the two cylindrical surfaces 2111 of the two convex portions 211 for cooling the crystal rod on the heat exchanger 20 at an upper portion is equal to the distance at a lower portion, ensuring a consistent cooling effect on the crystal rod when the heat exchanger 20 is in operation, which in turn can ensure the uniformity and the growth rate of the crystal rod when the heat exchange device is used in the single crystal furnace, i.e., an effect of improving quality of the crystal rod.

The guiding tube 30 provided in the present disclosure is disposed on an outside of the heat exchanger 20, an inner wall 31 of the guiding tube 30 is defined in a tapered structure matching with an outer peripheral wall 22 of the heat exchanger 20, and a predetermined gap is formed between the tapered structure and the outer peripheral wall 22. The predetermined gap between the guiding tube 30 and the heat exchanger 20 can be filled with an insulating material (such as a soft felt or a hard felt) when the heat exchange device is applied to the single crystal furnace. An outer wall 32 of the guiding tube 30 is defined in a cylindrical structure to match with an inner wall of a heat field (not shown), and the guiding tube 30 can divert protective gas such as argon when the guiding tube 30 is used in the single crystal furnace, to isolate a direct heat radiation from a heat field to the heat exchanger 20 to avoid a reverse effect of the heat exchanger 20 on the cooling for the crystal rod due to the direct heat radiation, which in turn can ensure the heat exchanger cooling for the crystal rod. It should be noted that the guiding tube 30 is provided with a shrinking bottom 33. An inner diameter of the shrinking bottom 33 is equal to the small diameter of the heat exchanger 20 to meet requirements of the heat exchange device for cooling the crystal rod when the heat exchange device is in a lifting and lowering motion.

The guiding tube 30 is provided with a lifting hook 310, and the lifting tube 10 is provided with a connecting plate 110 for hooks. Specifically, the connecting plate 110 for hooks is fixed to the transverse portion 12 of the lifting tube 10, a part away from the lifting tube 10 of the connecting plate 110 for hooks has at least one clamping slot 111, and the lifting hook 310 can rotatably clamp into the at least one clamping slot 111 of the connecting plate 110 for hooks to limitedly install the guiding tube 30 on the lifting tube 10. A limiting installation of the guiding tube 30 on the lifting tube 10 is achieved by the above lifting hook 310 and the connecting plate 110 for hooks, resulting in that the lifting tube 10 can drive the heat exchanger 20 and the guiding tube 30 to move at the same time, thus meeting requirements of lifting and lowering of the heat exchange device when the heat exchange device is used in the single crystal furnace. It should be noted that an installation of the guiding tube 30 on the lifting tube 10 is not limited to those shown in the figures, and to those skilled in the art, a fixing between the guiding tube 30 and the heat exchanger 20 can be done in other ways such as hinge connection, screw connection, etc., which will not be elaborated herein.

It could be understood that the guiding tube 30 is capable of driving the lifting hook 310 to rotate into the clamping slot 111 of the connecting plate 110 for hooks to meet use of the guiding tube 30 for assembly on the heat exchanger 20 and to facilitate clamping of the lifting hook 310 into the clamping slot 111 of the connecting plate 110 for hooks. In other words, the clamping slot 111 of the connecting plate 110 for hooks can be a curved structure to meet use of lifting hook 310 clamping into the clamping slot 111.

In addition, a part of the lifting hook 310 clamped into the clamping slot 111 of the connecting plate 110 for hooks is sheathed with a spring (not shown), resulting in a certain amount of margin between the connecting plate 110 for hooks and a limiting end 311 of the lifting hook 310. When the lifting tube 10 drives the heat exchanger 20 and the guiding tube 30 to lift, the heat exchanger 20 is driven to lift a certain height firstly, then the connecting plate 110 for hooks on the lifting tube 10 can drive the guiding tube 30 to lift through the lifting hook 310, so as to ensure that the heat exchanger 20 and the deflector tube 30 are accurately reset when the heat exchanger 20 and the deflector tube 30 are lowered, and ensure that the outer wall 32 of the guiding tube 30 can be driven by an elastic action of the spring to accurately adhere to the inner wall of the heat field.

Furthermore, the part away from the lifting tube 10 of the connecting plate 110 for hooks has a plurality of clamping slots 111 arranged along a radial direction of the guiding tube 30, and the lifting tube 10 can be adapted to limiting installations of guiding tubes 30 with different sizes, which in turn allows the lifting tube 10 to be adapted to heat exchangers 20 with different sizes. It should be noted that the plurality of clamping slots 111 can be arranged on both sides of the connecting plate 110 for hooks, or centrally on one side of connecting plate 110 for hooks, which will not be elaborated herein.

A lifting mechanism 40 is applied to the heat exchange device, and configured to drive the lifting tube 10 in the lifting and lowering motion along the growth direction of the crystal rod specifically. In the present disclosure, the lifting mechanism 40 can include a motor which drives the lifting tube 10 to lift and lower through a transmission mechanism. The transmission mechanism can include a specific screw and a nut, a worm gear and so on, which will not be elaborated herein.

A guiding component 50 is applied to the heat exchange device, and configured to guide and limit the lifting and lowering motion of the lifting tube 10, so as to ensure stability of the heat exchanger when the heat exchanger 20 is lifting and lowering, and avoid interference between the heat exchanger 20 and the crystal rod during the lifting and lowering motion.

Specifically, the guiding component 50 can include a first flange 51, a second flange 52, and an expansion tube 53 for connecting the first flange 51 and the second flange 52. The lifting tube 10 is disposed on a moving portion of the lifting mechanism 40 by the first flange 51, and the second flange 52 is disposed on a fixed portion of the lifting mechanism 40, so as to achieve a structure of the guiding component 50. The guiding component 50 is capable of stretching or compressing the expansion tube 53 in response to the lifting and lowering of the lifting tube 10 during operation. In other words, when the guiding component 50 is in operation, the first flange 51 and the second flange 52 can simultaneously guide the lifting tube 10. It should be noted that the expansion tube 53 cam be a corrugated tube.

In addition, it should be noted that a number of the lifting tube 10 is two, two lifting tubes 10 are connected by a flexible shaft 120, so as to ensure synchronization of the two lifting tubes 10 in the lifting and lowering motion. The heat exchange device further includes a detecting sensor, and the detecting sensor can includes a laser sensor or a micro switch. Specifically, the detecting sensor can detect the two lifting tubes 10 in a movement at the same position and feedback signals. The lifting and lowering of the two lifting tubes 10 can be detect by the detecting sensor and signals can be fed back, so as to ensure stability of the lifting and lowering motion of the two lifting tubes 10 to the heat exchanger 20.

The technical features of the above-described embodiments may be combined in any combination. For the sake of brevity of description, all possible combinations of the technical features in the above embodiments are not described. However, as long as there is no contradiction between the combinations of these technical features, all should be considered as within the scope of this disclosure.

The above-described embodiments are merely illustrative of several embodiments of the present disclosure, and the description thereof is relatively specific and detailed, but is not to be construed as limiting the scope of the disclosure. It should be noted that a number of variations and modifications may be made by those skilled in the art without departing from the spirit and scope of the disclosure. Therefore, the scope of the disclosure should be determined by the appended claims.

We claim:

1. A heat exchange device for a single crystal furnace, comprising a lifting tube and a heat exchanger, wherein the heat exchanger is disposed on the lifting tube, the lifting tube is capable of delivering a coolant into the heat exchanger;
the heat exchanger comprises an inner chamber for heat exchange, which is in a shape of a circular truncated cone;
at least one convex portion is defined by a chamber wall of the inner chamber for heat exchange partially projecting along a radial direction of the inner chamber for heat exchange, the at least one convex portion extends along a direction of an axis of the inner chamber for heat exchange, and a minimum distance between an end away from the chamber wall of the inner chamber for heat exchange of the at least one convex portion and the axis of the inner chamber for heat exchange is denoted as L, which is greater than or equal to a minimum radius of a cross section of the inner chamber for heat exchange along a direction perpendicular to the axis of the inner chamber for heat exchange.

2. The heat exchange device for the single crystal furnace of claim 1, wherein a number of the at least one convex portion is two, and two convex portions are symmetrically distributed on the chamber wall of the inner chamber for heat exchange.

3. The heat exchange device for the single crystal furnace of claim 2, wherein a surface of the end away from the chamber wall of the inner chamber for heat exchange of each of the two convex portions is defined as a cylindrical surface.

4. The heat exchange device for the single crystal furnace of claim 3, wherein a distance between the cylindrical surfaces of the two convex portions along the radial direction of the inner chamber for heat exchange is equal to a minimum diameter of the inner chamber for heat exchange.

5. The heat exchange device for the single crystal furnace of claim 1, wherein the heat exchange device further comprises a guiding tube disposed on an outside of the heat exchanger, an inner wall of the guiding tube is defined as a tapered structure matching with an outer peripheral wall of the heat exchanger, a predetermined gap is formed between the tapered structure and the outer peripheral wall, and an outer wall of the guiding tube is defined in a cylindrical structure.

6. The heat exchange device for the single crystal furnace of claim 5, wherein the guiding tube is provided with a lifting hook, the lifting tube is provided with a connecting plate for hooks, a part away from the lifting tube of the connecting plate for hooks has at least one clamping slot, and the lifting hook is capable of rotatably clamping into the at least one clamping slot of the connecting plate for hooks to limitedly install the guiding tube on the lifting tube.

7. The heat exchange device for the single crystal furnace of claim 6, wherein the part away from the lifting tube of the connecting plate for hooks has a plurality of clamping slots arranged along a radial direction of the guiding tube.

8. The heat exchange device for the single crystal furnace of claim 1, wherein the heat exchange device further comprises a lifting mechanism which is capable of driving the heat exchanger via the lifting tube to move in a lifting and lowering motion.

9. The heat exchange device for the single crystal furnace of claim 8, wherein the heat exchange device further comprises a guiding component which is penetrated by the lifting tube, and the guiding component is configured for guiding and limiting a lifting and lowering motion of the lifting tube.

10. The heat exchange device for the single crystal furnace of claim 9, wherein the guiding component comprises a first flange, a second flange, and an expansion tube for connecting the first flange and the second flange, the lifting tube is disposed on a moving portion of the lifting mechanism by the first flange, and the second flange is disposed on a fixed portion of the lifting mechanism.
